(19) United States
(12) Patent Application Publication
(10) Pub. No.: US 2026/0327855 A1
(43) Pub. Date: Oct. 22, 2026

(54) Method of producing platinum-loaded single-crystal spherical carbon nanoparticles

(71) Applicant: M. TECHNIQUE CO., LTD., Izumi-shi (JP)

(72) Inventors: Hideki Ohkawa, Izumi-shi (JP); Masakazu Enomura, Izumi-shi (JP)

(21) Appl. No.: 19/157,568

(22) PCT Filed: Feb. 27, 2023
(86) PCT No.: PCT/JP2023/007011

§ 371 Date: Aug. 18, 2025

(51) Int. Cl. C30B 31/04; C30B 29/02; C30B 29/60

(52) U.S. Cl. CPC C30B 31/04; C30B 29/02; C30B 29/60

(57) ABSTRACT

The present application is a method of producing platinum-loaded single-crystal spherical carbon nanoparticles in which platinum particles are loaded on a surface of single-crystal spherical carbon nanoparticles, comprising mixing a single-crystal spherical carbon nanoparticle raw material liquid containing carbon halide and a platinum-loaded single-crystal spherical carbon nanoparticle reduction liquid containing an aromatic compound anion generated from lithium, sodium or potassium and the aromatic compound to produce single-crystal spherical carbon nanoparticles; and continuously adding a platinum raw material liquid containing a platinum halide to the mixture to produce platinum-loaded single-crystal spherical carbon nanoparticles. The produced platinum-loaded single-crystal spherical carbon nanoparticles do not have toxicities to living organisms, can be densely packed as electrode materials for solar cells and secondary ion batteries, and can be used for a negative electrode for lithium batteries, a fuel cell catalyst or an electrode material for solar cells, in which low electrical conductivity is improved.

### TECHNICAL FIELD

The present invention relates to a method of producing platinum-loaded single-crystal spherical carbon nanoparticles.

### BACKGROUND ART

Carbon nanoparticles are nanoparticles made of carbon atoms. Carbon nanoparticles with a particle diameter of less than 10 nm are also called carbon quantum dots. Quantum dots that are formed from metal elements such as CdSe and CdTe and exhibit fluorescence are known as quantum dots. However, these quantum dots are not suitable for use within the human body. Thus, efforts have been made to find alternative materials.

It is known that carbon nanoparticles can be produced by a top-down or bottom-up method. As a top-down method of producing carbon nanoparticles, known are, for example, a method of producing carbon nanoparticles from at least micron-sized carbon materials such as graphite, carbon nanotubes and diamonds, using a laser ablation, arc discharge, or electrochemical method. On the other hand, as a bottom-up method of producing carbon nanoparticles, known are, for example, a method of heat-treating pure water or an organic solvent under a high temperature and high pressure condition known as a hydrothermal method, and a chemical vapor deposition method (CVD).

When carbon nanoparticles are used for drug delivery within a human body, it is necessary to treat hydrophobic carbon nanoparticles to make them hydrophilic. For that purpose, an oxidation reaction under the air atmosphere is performed, or after a surfactant is mixed and dispersed in an aqueous solution, surface of the carbon nanoparticle is subjected to a hydrophilic treatment using an oxidation agent or the like. Such hydrophilic treatment of carbon nanoparticles in an aqueous solution combined with a surfactant requires a cleaning process to remove the surfactant after the treatment, and such complicated treatment has been a problem.

Claim 1 of Patent Literature 1 describes a carbon nanoparticle phosphor containing carbon atoms, oxygen atoms, nitrogen atoms, and optionally hydrogen atoms. Because of the C—N bond and the C—O bond, the carbon nanoparticle phosphor can be dispersed in an aqueous solution. Claim 9 of Patent Literature 1 describes that the carbon nanoparticle phosphor is produced by a method comprising a step of hydrothermal synthesis of a solution in which an organic substance selected from the group consisting of citric acid, benzoic acid, glucose, fructose and sucrose; and an amine; and one or more selected from inorganic acids and acetic acid are dissolved in a water-soluble solvent. However, Patent Literature 1 does not disclose the spatial lattice, which is structural information of the carbon nanoparticle phosphor, or a platinum-loaded carbon nanoparticle phosphor.

Patent Literature 2 describes a carbon composite for an oxygen reduction catalyst comprising nanosheet-like graphene oxide or its reduced product and carbon quantum dots (Claim 1). Patent Literature 2 describes that carbon quantum dots may be carbon obtained by a conventional hydrothermal reaction, for example, carbon obtained by heating an aqueous solution containing a carbon source compound such as citric acid and a nitrogen source compound such as ethylenediamine at a temperature higher than the boiling point of water (Claim 6, [0031], etc.). However, Patent Literature 2 does not disclose that the carbon quantum dots are single-crystal and spherical, or that platinum is loaded on the carbon quantum dots.

Patent Literature 3 describes a method of producing luminescent nanocarbon comprising a reaction step of reacting a raw material solution containing a carbon source compound and a nitrogen source compound by a solvothermal synthesis method or the like (Claim 1, [0013]). This luminescent nanocarbon is produced by hydrothermal synthesis similar to the production method of Patent Literature 1. However, Patent Literature 3 does not disclose that the luminescent nanocarbon is single-crystal and spherical, or that platinum is loaded on the luminescent nanocarbon.

Patent Literature 4 describes a method of forming carbon dots, comprising: (a) mixing carbon powders with sulfuric acid and nitric acid to form a carbon powder mixture; (b) heating the carbon powder mixture under reflux to form a refluxed carbon powder mixture; (c) cooling the refluxed carbon powder mixture; and (d) neutralizing the refluxed carbon powder mixture to form a neutralized carbon powder mixture containing solubilized carbon dots (Claim 1, [0036]). By using acid in this step (a), the carbon powders are oxidized to a quantum size of 1.5 to 6 nm ([0037], [0038]). The carbon dots prepared by the above formation method have abundant carboxyl groups on their surface and may have negative charges on the carboxyl groups ([0048]). The carbon dots are different from the single-crystal spherical carbon nanoparticles produced by the production method of the present invention because they have abundant carboxyl groups on their surface. Further, Patent Literature 4 does not disclose that the carbon dots are single-crystal and spherical, or that platinum is loaded on the carbon dots.

Patent Literature 5, filed by the applicant of the present application, describes a method of producing semiconductor microparticles using a fluid processing apparatus equipped with relatively rotating processing surfaces that can approach and separate (Claim 1). Patent Literature 5 describes that specific examples of the semiconductor element are an element selected from the group consisting of silicon, germanium, carbon and tin ([0037]). However, Patent Literature 5 does not describe specific examples in which the semiconductor element is carbon. The platinum-loaded single-crystal spherical carbon nanoparticles of the present invention cannot be produced based on Patent Literature 5. Furthermore, Patent Literature 5 does not disclose that the nanoparticles are single-crystal and spherical, or that platinum is loaded.

Patent Literature 6, filed by the applicant of the present application, describes a method of producing metal-loaded carbon particles using a fluid processing apparatus equipped with relatively rotating processing surfaces that can approach and separate ([0221] to [0263]). For example, in Example B1, platinum-loaded carbon black was produced by reacting a solution in which carbon black is mixed with a reduction agent, and a dinitrodiammine platinum nitrate solution. However, the carbon black is used as it is as a raw material, and Patent Literature 6 does not disclose that the carbon particles are single crystal and spherical.

Patent Literature 7 describes a fuel cell comprising a surface nanostructure 3 having platinum catalyst nanoparticles 4 and carbon nanoparticles 5 (claim 1, FIG. 1, etc.). However, Patent Literature 7 does not disclose that the carbon nanoparticles are single crystal and spherical.

Non-Patent Literature 1 describes that amine-terminated carbon quantum dots were synthesized by reducing carbon tetrachloride with a hydride reduction agent such as lithium aluminum hydride to obtain carbon quantum dots, and then reacting with an arylamine in the presence of a platinum catalyst. Since the carbon quantum dots of Non-Patent Literature 1 have NH₂ groups on their surface, they are different from the platinum-loaded single-crystal spherical carbon nanoparticles of the present invention. Further, Non-Patent Literature 1 does not disclose that the carbon quantum dots are single-crystal and spherical, or that platinum is loaded on carbon quantum dots.

### PRIOR ART DOCUMENT

### Patent Literature

Patent Literature 1: WO 2018/163955
Patent Literature 2: JP 2019-155349
Patent Literature 3: JP 2021-183548
Patent Literature 4: JP 2019-511442
Patent Literature 5: JP 4458202
Patent Literature 6: JP 5500597
Patent Literature 7: WO 2009/128203

### Non-Patent Literature

Non-Patent Literature 1: Journal of Materials Chemistry, Volume 2, pp. 6025-6031 (2014)

### SUMMARY OF THE INVENTION

### Problem to be Solved by the Invention

The problem of the present invention is to provide a method of producing carbon nanoparticles which can be used as a non-toxic catalyst or an electrode material, improve the electrical conductivity of electrode materials for secondary batteries, and further can be densely packed.

### Means to Solve the Problem

As a result of intensive research for solving the above problems, the present inventors have found that platinum-loaded single-crystal spherical carbon nanoparticles could be produced by reacting a solution containing a carbon halide with a reduction agent containing an anion of an aromatic compound generated by mixing lithium, sodium or potassium with the aromatic compound, followed by continuously reacting the obtained mixture with a solution containing a platinum halide; and that the produced platinum-loaded single-crystal spherical carbon nanoparticles could be used as a battery electrode with improved electrical conductivity over conventional carbon nanoparticles, making it possible to increase the filing density of a battery, and could also be used as a non-toxic catalyst. Thereby, the present inventors have completed the present invention.

Namely, the present inventions are as follows.
[1]A method of producing platinum-loaded single-crystal spherical carbon nanoparticles in which platinum particles are loaded on a surface of single-crystal spherical carbon nanoparticles, the method comprising:
a step of mixing a single-crystal spherical carbon nanoparticle raw material liquid containing a carbon halide and a platinum-loaded single-crystal spherical carbon nanoparticle reduction liquid containing an anion of an aromatic compound generated from lithium, sodium or potassium and the aromatic compound to produce single-crystal spherical carbon nanoparticles; and
a step of continuously adding a platinum raw material liquid containing a platinum halide to the obtained mixture to produce platinum-loaded single-crystal spherical carbon nanoparticles.
[2] The method according to [1], wherein an average value of a circularity calculated by the formula: 4πS/Z² is 0.8 or more, when using the perimeter (Z) and the area (S) of the projected image of the single-crystal spherical carbon nanoparticle observed by a transmission electron microscope.
[3] The method according to [1] or [2], wherein the average particle diameter of the single-crystal spherical carbon nanoparticles is 1 nm to 200 nm.
[4] The method according to any one of [1] to [3], wherein the single-crystal spherical carbon nanoparticle raw material liquid and the platinum-loaded single-crystal spherical carbon nanoparticle reduction liquid are mixed using an apparatus to produce single-crystal spherical carbon nanoparticles; and continuously the platinum raw material liquid containing a platinum halide is added to the obtained mixture to produce platinum-loaded single-crystal spherical carbon nanoparticles,
wherein the apparatus comprises a fluid pressure imparting mechanism for imparting a predetermined pressure to fluids to be processed; at least two processing members of a first processing member and a second processing member, the second processing member being capable of approaching to and separating from the first processing member; and a rotation drive mechanism for rotating the first processing member and the second processing member relative to each other; and
wherein the at least two processing members provide at least two processing surfaces of a first processing surface and a second processing surface disposed in a position facing with each other,
each of the processing surfaces constitute part of a sealed flow path through which the fluid to be processed under the predetermined pressure is passed,
the processing surfaces are for mixing and reacting two or more fluids to be processed, at least one of which contains a reactant, with each other,
of the first and second processing members, at least the second processing member is provided with a pressure-receiving surface, and at least part of the pressure-receiving surface is comprised of the second processing surface,
the pressure-receiving surface receives pressure applied to the fluids to be processed by the fluid pressure imparting mechanism and thereby generates a force to move in the direction of separating the second processing surface from the first processing surface,
the fluids to be processed under the predetermined pressure are passed between the first and second processing surfaces being capable of approaching to and separating from each other, at least one of which rotates relative to the other, whereby the fluids to be processed form a thin film fluid while passing between the first and second processing surfaces,
the apparatus further comprises an introduction path independent of the flow paths through which the fluids to be processed under the predetermined pressure are passed; and at least one opening leading to the introduction path and being arranged in at least either the first processing surface or the second processing surface, and
at least one of the fluids to be processed is sent from the introduction path and introduced into between the first and second processing surfaces, and a reactant contained at least in any one of the aforementioned fluids to be processed is mixed with the fluids to be processed other than the fluid containing the reactant in the thin film fluid.
[5] The method according to [4], wherein the opening is located downstream of a point at which the flow of the fluids to be processed that is passed between the two processing surfaces becomes a laminar flow.
[6] The method according to any one of [1] to [5], wherein the molar ratio of the lithium, sodium or potassium and the halogenated carbon is 7:1 to 4:1.
[7] The method according to any one of [1] to [6], wherein the aromatic compound is at least one selected from the group consisting of biphenyl, naphthalene, 1,2-dihydronaphthalene, anthracene, phenanthrene and pyrene.
[8] The method according to [7], wherein when the aromatic compound is biphenyl, naphthalene or anthracene, an IR absorption spectrum of the platinum-loaded single-crystal spherical carbon nanoparticle reduction liquid shows an absorption peak in the wavenumber range of 1200 cm⁻¹ to 1100 cm⁻¹.
[9] The method according to any one of [1] to [8], wherein when the aromatic compound is biphenyl, naphthalene or anthracene, an ¹H-NMR spectrum of the platinum-loaded single-crystal spherical carbon nanoparticle reduction liquid shows at least four peaks of chemical shifts between 5.5 ppm and 6.5 ppm.
[10] The method according to any one of [1] to [9], wherein when the aromatic compound is biphenyl, naphthalene or anthracene, an ⁷Li-NMR spectrum of the platinum-loaded single-crystal spherical carbon nanoparticle reduction liquid shows a peak of chemical shifts at 2 ppm or more.
[11] The method according to any one of [1] to [10], wherein the solvent contained in the platinum-loaded single-crystal spherical carbon nanoparticle reduction liquid is tetrahydrofuran, 2-methyltetrahydrofuran or dimethoxyethane with residual water of 10 ppm or less.
[12] The method according to any one of [1] to [11], wherein the solvent contained in the platinum-loaded single-crystal spherical carbon nanoparticle reduction liquid is tetrahydrofuran which contains a phenolic polymerization inhibitor, and has residual water of 10 ppm or less and residual oxygen concentration of less than 0.1 ppm.
[13] The method according to any one of [1] to [12], wherein the solvent contained in the single-crystal spherical carbon nanoparticle raw material liquid is tetrahydrofuran, 2-methyltetrahydrofuran, or dimethoxyethane having residual water of 10 ppm or less and residual oxygen concentration of less than 0.1 ppm.
[14] The method according to any one of [1] to [13], wherein the halogenated carbon is carbon tetrachloride, carbon tetrabromide, or carbon tetraiodide.
[15] The method according to any one of [1] to [14], wherein the platinum halide is hydrogen hexachloroplatinate (IV) hexahydrate or platinum chloride (IV).
[16] The method according to any one of claims 1 to 15, wherein the single-crystal spherical carbon nanoparticles are hexagonal.
[17] The method according to any one of [1] to [16], wherein in an IR absorption spectrum, the platinum-loaded single-crystal spherical carbon nanoparticles have an absorption peak in the wavenumber range of 2800 cm⁻¹ to 3000 cm⁻¹, and the area of the absorption peak of 1000 cm⁻¹ to 1100 cm⁻¹ obtained by waveform separation of the wavenumber range of 900 cm⁻¹ to 1900 cm⁻¹ is 15% or less of the total area of absorption peaks in the wavenumber range of 900 cm⁻¹ to 1900 cm⁻¹.
[18] The method according to any one of [1] to [17], wherein in an IR absorption spectrum of the platinum-loaded single-crystal spherical carbon nanoparticles, the area of the absorption peak of 1300 cm⁻¹ to 1400 cm⁻¹ obtained by waveform separation of the wavenumber range of 900 cm⁻¹ to 1900 cm⁻¹ is 10% or less of the total area of absorption peaks in the wavenumber range of 900 cm⁻¹ to 1900 cm⁻¹.
[19] The method according to any one of [1] to [18], wherein in a fluorescence spectrum, the platinum-loaded single-crystal spherical carbon nanoparticles have a fluorescence maximum in a wavelength range of 400 nm to 500 nm when excited by a light with a wavelength of 240 nm.
[20] Platinum-loaded single-crystal spherical carbon nanoparticles in which platinum is loaded on a surface of single-crystal spherical carbon nanoparticles having an average particle diameter of 1 nm to 30 nm.

### Effects of the Invention

The platinum particle-loaded single-crystal spherical carbon nanoparticles can be produced by the production method of the present invention. The platinum-loaded single-crystal spherical carbon nanoparticles produced by the production method of the present invention are loaded with platinum particles having excellent electrical conductivity, so that the electrical conductivity of the carbon nanoparticles can be improved. In addition, since the platinum-loaded single-crystal spherical carbon nanoparticles do not have toxicities to living organisms as compound semiconductors made of cadmium, selenium, tellurium, etc. have, there is no need to recover them after use as catalysts or battery materials. Furthermore, since the platinum-loaded single-crystal spherical carbon nanoparticles are spherical, they can be densely packed as electrode materials for solar cells and secondary ion batteries, and can be used for a negative electrode for lithium batteries, a fuel cell catalyst or an electrode material for solar cells.

### BRIEF DESCRIPTION OF THE DRAWINGS

FIG. 1 shows an IR absorption spectrum of a naphthalene anion in the platinum particle-loaded single-crystal spherical carbon nanoparticle reduction liquid.

FIG. 2 shows a ¹H-NMR spectrum of the platinum particle-loaded single-crystal spherical carbon nanoparticle reduction liquid.

FIG. 3 shows ⁷Li-NMR spectrum of the platinum particle-loaded single-crystal spherical carbon nanoparticle reduction liquid.

FIG. 4 shows a TEM observation image of the platinum-loaded single-crystal spherical carbon nanoparticles prepared in Example 1-1.

FIG. 5 shows a TEM observation image of platinum loaded on the platinum-loaded single-crystal spherical carbon nanoparticles prepared in Example 1-1, and the measured length of 5 lattice spacings.

FIG. 6 shows an STEM observation image of the platinum-loaded single-crystal spherical carbon nanoparticles prepared in Example 1-2 and line analysis of platinum by STEM-EDS thereof.

FIG. 7 shows an IR spectrum of the platinum-loaded single-crystal spherical carbon nanoparticles prepared in Example 1-1, and waveform separation spectrum thereof (2800 cm⁻¹ to 3000 cm⁻¹).

FIG. 8 shows an IR spectrum of the platinum-loaded single-crystal spherical carbon nanoparticles prepared in Example 1-1, and waveform separation spectrum thereof (900 cm⁻¹ to 1900 cm⁻¹).

FIG. 9 shows a fluorescence spectrum of the platinum-loaded single-crystal spherical carbon nanoparticles prepared in Example 1-2.

FIG. 10 shows an X-ray diffraction pattern of the platinum-loaded single-crystal spherical carbon nanoparticles prepared in Example 1-4.

FIG. 11 shows an STEM observation image of the platinum-loaded single-crystal spherical carbon nanoparticles prepared in Example 3-1, and surface analysis of platinum by STEM-EDS.

### EMBODIMENT FOR CARRYING OUT THE INVENTION

Hereinafter, embodiments of the present invention will be described. However, the present invention is not limited to only the embodiments described below. Further, an exemplary application thereof to a light emitting material that emits fluorescence will be described, but the applications of the platinum-loaded single-crystal spherical carbon nanoparticles produced by the production method of the present invention are not limited thereto.

### 1. Platinum-Loaded Single-Crystal Spherical Carbon Nanoparticles

The platinum-loaded single-crystal spherical carbon nanoparticles produced by the production method of the present invention are single-crystal spherical carbon nanoparticles on which surface platinum particles are loaded. The single-crystal spherical carbon nanoparticles contained in the platinum-loaded single-crystal spherical carbon nanoparticles are single-crystals and spherical. The average particle diameter of the single-crystal spherical carbon nanoparticles is preferably 1 nm to 200 nm. In case of the average particle diameter of 200 nm or more, when using the platinum-loaded single-crystal spherical carbon nanoparticles as a negative electrode material for a secondary battery, it is difficult to achieve packing at high density. The single-crystal spherical carbon nanoparticles are hexagonal. This hexagonal space lattice can have a simple lattice structure or a rhombohedral lattice structure. The single-crystal spherical carbon nanoparticles are spherical, and may be approximately spherical. The average value of circularity of the single-crystal spherical carbon nanoparticles is preferably 0.85 or more, more preferably 0.90 or more, still more preferably 0.95 or more. The average value of circularity is calculated using the formula: 4πS/Z² using the perimeter (Z) and area (S) of a projected image of the single-crystal spherical carbon nanoparticle observed by a transmission electron microscope. When attempting to utilize fluorescence from the platinum-loaded single-crystal spherical carbon nanoparticles, the average particle diameter of the single-crystal spherical carbon nanoparticles is preferably 1.2 nm to 10 nm, more preferably 1.5 nm to 7 nm, more preferably 2 nm to 5 nm.

The average particle diameter of the platinum particles is, for example, 1 nm to 10 nm, preferably 1.5 nm to 5 nm, more preferably 1 nm to 3 nm, and further preferably 0.2 nm to 2 nm.

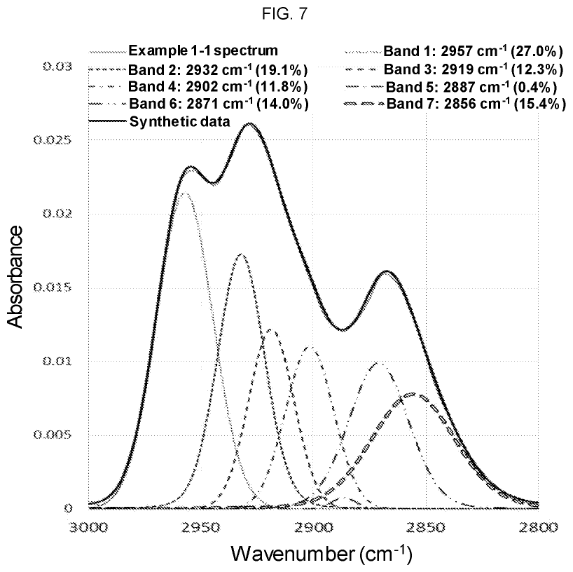

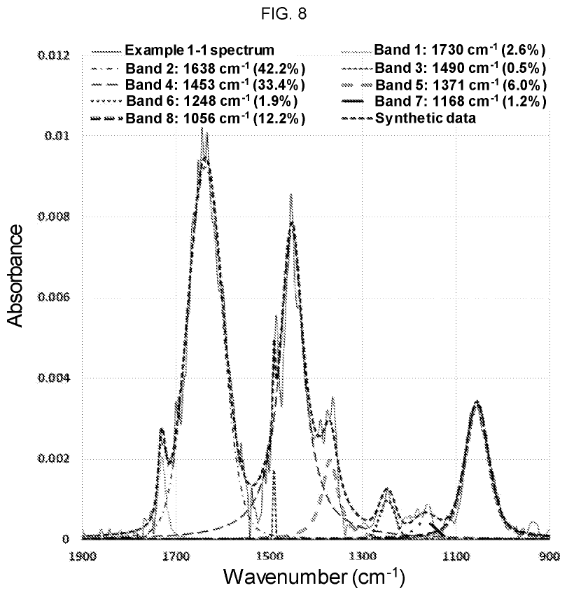

It is known that carbon has various structures, including graphene layers based on C═C bonds consisting of carbon atoms with sp2 hybrid orbital, graphite in which the graphene layers are stacked in the c-axis direction, and carbon nanotube structure. However, since these structures do not have a band gap, the excited electrons generated by the excitation light and the holes which are electron vacancies left by the excited electrons, immediately recombine and do not generate fluorescence. For this reason, it is necessary to generate a band gap in carbon made of carbon atoms with sp2 hybrid orbital by some method. One of methods for this purpose is to cut the bonding region of carbon atoms with sp2 hybrid orbital in the graphene layer, and to introduce bonds of carbon atoms with sp3 hybrid orbital by bonding the carbon atoms to carbon atoms or elements other than carbon atoms. The bond of carbon atoms with sp3 hybrid orbital can generate C—H bonds or C—O bonds by bonding hydrogen or oxygen to the edges of the graphene layer. Therefore, preferable is the carbon nanoparticles having a stacked structure of graphene layers in which C—H bonds are present inside the graphene layer constituting the single-crystal spherical carbon nanoparticles and C—O bonds are present at the edge of the graphene layer. The surface functional groups on the single-crystal spherical carbon nanoparticles can be confirmed, for example, by the presence of absorption in the wavenumber range of 2800 cm⁻¹ to 2950 cm⁻¹ in the IR absorption spectrum attributed to stretching vibrations of C—H bond, and absorption in the wavenumber range of 1000 cm⁻¹ to 1100 cm⁻¹ attributed to the stretching vibrations of C—O bond. As shown in FIG. 7 and FIG. 8, the platinum-loaded single-crystal spherical carbon nanoparticles of Example 1-1 has absorption peaks of C—H bond at 2932 cm⁻¹ and 2957 cm⁻¹, and 2856 cm⁻¹ and 2871 cm⁻¹ and an absorption peak of C—O bond at 1056 cm⁻¹. Accordingly, the structural change that contributes to the generation of a band gap due to the presence of a carbon atom with sp3 hybrid orbital, can be confirmed.

The platinum-loaded single-crystal spherical carbon nanoparticles are preferably platinum-loaded single-crystal spherical carbon nanoparticles wherein in an IR absorption spectrum, an area of the absorption peak of the platinum-loaded single-crystal spherical carbon nanoparticles in 1000 cm⁻¹ to 1100 cm⁻¹ (stretching vibration of C—O bond) obtained by waveform separation of the wavenumber range of 900 cm⁻¹ to 1900 cm⁻¹ is 15% or less (ratio of C—O bond), more preferably 2% or more and 15% or less, even more preferably 2% or more and 10% or less, and even further more preferably 2% or more and 8.5% or less of the total area of absorption peaks in the wavenumber range of 900 cm⁻¹ to 1900 cm⁻¹.

The platinum-loaded single-crystal spherical carbon nanoparticles are preferably platinum-loaded single-crystal spherical carbon nanoparticles that exhibit a fluorescence maximum in the wavelength range of 400 nm to 600 nm in the fluorescence spectrum.

The platinum-loaded single-crystal spherical carbon nanoparticles are preferably platinum-loaded single-crystal spherical carbon nanoparticles wherein in an IR absorption spectrum, an area of the absorption peak of the platinum-loaded single-crystal spherical carbon nanoparticles in 1300 cm⁻¹ to 1400 cm⁻¹ obtained by waveform separation of the wavenumber range of 900 cm⁻¹ to 1900 cm⁻¹ is 10% or less (ratio of C—N bond), more preferably 8% or less, even more preferably 6.5% or less of the total area of absorption peaks in the wavenumber range of 900 cm⁻¹ to 1900 cm⁻¹.

It is known that fluorescence of carbon nanoparticles occurs by three different mechanisms below.
(A) Control of fluorescence color by controlling a physical factor of changing the band gap of electron energy according to the particle diameter of carbon nanoparticles into which carbon atoms with sp3 hybrid orbital are introduced (known as quantum effect).
(B) Control of fluorescence color via surface substituents in a state where a various substituent such as an alkyl group with a different molecular chain length and an amino group is chemically bonded to the surface of carbon nanoparticles by surface modification of treating the carbon nanoparticles with a various chemical.
(C) Control of fluorescent color by a chemical factor by utilizing a compositional change mediated by oxygen or nitrogen contained in carbon nanoparticles.

In the platinum-loaded single-crystal spherical carbon nanoparticles of the present invention, (A) quantum effect mechanism and (C) oxygen mediated mechanism of the three mechanisms (A) to (C) act synergistically to produce fluorescence. This is different from the mechanism of the amino group-terminated carbon nanoparticles of Non Patent Literature 1, which use (A) quantum effect mechanism and (B) surface modification mechanism. The platinum-loaded single-crystal spherical carbon nanoparticles of the present invention preferably exhibit a fluorescence maximum in the wavelength range of 400 nm to 600 nm.

### 2. Method of Producing Platinum-Loaded Single-Crystal Spherical Carbon Nanoparticles

The production method of the present invention is a method of producing platinum-loaded single-crystal spherical carbon nanoparticles in which platinum particles are loaded on a surface of single-crystal spherical carbon nanoparticles, the method comprising: a step of mixing a single-crystal spherical carbon nanoparticle raw material liquid containing a carbon halide (Liquid B) and a platinum-loaded single-crystal spherical carbon nanoparticle reduction liquid containing an anion of an aromatic compound generated from lithium, sodium or potassium and the aromatic compound (Liquid A) to produce single-crystal spherical carbon nanoparticles; and a step of continuously adding a platinum raw material liquid containing a platinum halide (Liquid C) to the obtained mixture to produce platinum-loaded single-crystal spherical carbon nanoparticles. For example, platinum-loaded single-crystal spherical carbon nanoparticles can be continuously produced by mixing the single-crystal spherical carbon nanoparticle raw material liquid (Liquid B) and the platinum raw material liquid (Liquid C) with the platinum-loaded single-crystal spherical carbon nanoparticle reduction liquid (Liquid A) in a thin film fluid formed between two processing surfaces that are arranged opposite to each other and can approach and separate, at least one of which rotates relative to the other.

### (Single-Crystal Spherical Carbon Nanoparticle Raw Material Liquid (Liquid B))

The raw material of the single-crystal spherical carbon nanoparticles is not particularly limited as long as it is a substance capable of precipitating the single-crystal spherical carbon nanoparticles by reduction. For example, the raw material may be preferably carbon tetrahalide, more preferably carbon tetrachloride, carbon tetrabromide, carbon tetraiodide, and the like. and even more preferably carbon tetrachloride, carbon tetrabromide, and the like.

### (Platinum Raw Material Liquid (Liquid C))

The raw material of the platinum particles loaded on the single-crystal spherical carbon nanoparticles is not particularly limited as long as it is a substance that can be reduced to make platinum particles be loaded on the surface of the single-crystal spherical carbon nanoparticles. For example, the raw material may be preferably platinum halides, more preferably hydrogen hexachloroplatinate (IV) hexahydrate (H₂PtCl₆·6H₂O) and platinum (IV) chloride (PtCl₄).

### (Solvent)

The solvent of the platinum-loaded single-crystal spherical carbon nanoparticle reduction liquid (Liquid A), the single-crystal spherical carbon nanoparticle raw material liquid (Liquid B) and the platinum raw material liquid (Liquid C) is not particularly limited as long as it can dissolve the single-crystal spherical carbon nanoparticle raw material and the platinum raw material, can reduce the platinum raw material to load platinum particles on the single-crystal spherical carbon nanoparticles, and is inert and does not affect the reduction reaction. Preferably, the solvent includes ether, etc., more preferably tetrahydrofuran (THF), 2-methyltetrahydrofuran, 1,2-dimethoxyethane (DME), or a mixture thereof, and even more preferably THE or 2-methyltetrahydrofuran.

### (Residual Water/Residual Oxygen in Solvent)

It is preferable to use a solvent in which the residual water in the platinum-loaded single-crystal spherical carbon nanoparticle reduction liquid (Liquid A), the single-crystal spherical carbon nanoparticle raw liquid (Liquid B) and the platinum raw liquid (Liquid C) is 10 ppm or less. The reason is that when the single-crystal spherical carbon nanoparticles are produced by a reduction reaction in a solvent, if the residual water is more than 10 ppm, the oxidation reaction of the graphene layer becomes significant, and causes distortion in the graphite structure generated by stacking the graphene layers in the c-axis direction. Further, when the graphene layers cannot be stacked on each other, there will be an inconvenience that the single-crystal spherical carbon nanoparticles will not be formed. The residual oxygen concentration in the solvent used in the present invention is preferably less than 0.1 ppm.

### (Platinum-Loaded Single-Crystal Spherical Carbon Nanoparticle Reduction Liquid (Liquid A))

The reduction substance contained in the platinum-loaded single-crystal spherical carbon nanoparticle reduction liquid is not particularly limited as long as it can reduce the raw material of the single-crystal spherical carbon nanoparticles in the platinum-loaded single-crystal spherical carbon nanoparticle raw material liquid, and the platinum raw material, and can precipitate platinum particles as platinum-loaded single-crystal spherical carbon nanoparticles. Examples of the reduction substance include a combination of metal lithium, sodium or potassium with an aromatic compound, and more preferably a combination of metal lithium with an aromatic compound.

Examples of the aromatic compound include those that can receive one electron from metal lithium to produce a lithium ion and an aromatic compound anion. The aromatic compound anion with one electron transferred has one electron in the lowest unoccupied molecular orbital (LUMO) of the aromatic compound, and thus is an anion radical. For example, when the raw material of the single-crystal spherical carbon nanoparticles is carbon tetrahalide, the potential of the aromatic compound anion needs to be less than −1.9 V in order to reduce carbon tetrahalide to carbon nanoparticles, because the reduction potential of carbon tetrachloride is −1.9 V. Here, the potential is a value relative to silver (Ag)/silver chloride (AgCl) as a standard electrode (reference electrode). Examples of the aromatic compound whose potential is less than −1.9V, include naphthalene (−2.53V), biphenyl (−2.68V), 1,2-dihydronaphthalene (−2.57V), phenanthrene (−2.49V), anthracene (−2.04V), pyrene (−2.13V), and a mixture thereof, preferably naphthalene, biphenyl, and the like. On the other hand, tetracene (−1.55V) and azulene (−1.62V) are not suitable for reducing carbon tetrachloride.

Examples of the molar ratio of metal lithium, sodium or potassium and the aromatic compound include 1:1 to 1:5, preferably 1:1 to 1:1.5, and more preferably 1:1 to 1:1.2.

Examples of the molar ratio of metal lithium, sodium or potassium and the raw material of the single-crystal spherical carbon nanoparticles include 10:1 to 1.2:1, preferably 7:1 to 1.5:1, more preferably 5:1 to 3:1. It is preferable to use metal lithium, sodium or potassium in excess of the raw material of the single-crystal spherical carbon nanoparticles. By using an excessive amount of metal lithium, sodium or potassium, the platinum-loaded single-crystal spherical carbon nanoparticles can be produced. When using metal lithium, sodium or potassium in an amount smaller than that of the raw material of the single-crystal spherical carbon nanoparticles, for example, when using metal lithium, sodium or potassium in an amount of ¾ of the amount of the raw material, the raw material would not be completely reduced, so that halogen atoms derived from the raw material remain in the single-crystal spherical carbon nanoparticles, and the resulting carbon nanoparticles become not spherical. Examples of the solvent of the platinum-loaded single-crystal spherical carbon nanoparticle reduction liquid include the above solvent used in the single-crystal spherical carbon nanoparticle raw material liquid. The concentration of metal lithium, sodium or potassium in the single-crystal spherical carbon nanoparticle reduction liquid is not particularly limited, but is determined according to the molar ratio of metal lithium, sodium or potassium to the raw material of the single-crystal spherical carbon nanoparticles described above.

### (Low Temperature Storage of the Reduction Liquid)

Alkali metals can be dissolved in an ether-based organic solvent in the coexistence of an aromatic compound. However, the reduction power is obtained from the aromatic compound anion generated when the alkali metal dissolves and the electron generated thereby is transferred to the LUMO of the aromatic compound. Explained in the case where the alkali metal is metal lithium, the aromatic compound is naphthalene (NPT), and the solvent is THF, the structure in the reduction liquid that generates the reduction power, is preferably a structure (Li⁺·NPT^{⋅-}) in which the lithium cation (Li⁺) and the naphthalene anion (NPT^{⋅-}) both generated after electron transfer to the aromatic compound are directly bonded by Coulomb force without solvent intervention, or a structure (Li⁺·THF·NPT^{⋅-}) in which the solvent THE is intervened between the lithium cation and the naphthalene anion. When the storage temperature is 25 °C or higher, these solution structures have a problem that the lithium cation (Li⁺) and the naphthalene anion (NPT^{⋅-}) are respectively solvated and bonded by Coulomb force in a mutually solvated structure (Li⁺·THF·THF·NPT^{⋅-}), resulting in a decrease in reduction power. For this reason, in the production method of the present invention, the temperature of the platinum-loaded single-crystal spherical carbon nanoparticle reduction liquid after its preparation is controlled to be maintained at less than 10 °C, and the reduction power can be maintained by controlling so that the bond between the naphthalene anion (NPT^{⋅-}) and the lithium cation (Li⁺) due to Coulomb force can be stably present.

### (Solvation at Low Temperature)

A structure in which an alkali metal cation and an aromatic compound anion are directly bonded without solvent intervention has the highest reduction power. The distribution of the particle diameters of the carbon nanoparticles can be controlled by maintaining this structure. When the reduction liquid is stored at 25 °C or above, there is a high probability that the solvent molecules will become intervened between these anions. In an equilibrium state where ions are directly bonded to each other by Coulomb force at a low temperature, even if the liquid is cooled to a low temperature during the preparation of the carbon nanoparticles, the solvent molecules cannot overcome the Coulomb force and enter between the cation and the anion. Therefore, the storage temperature after liquid preparation is important.

### (Suppression of Solvent Reduction)

The necessity of low temperature storage of the reduction liquid is to maintain a high reduction power and thereby suppress the distribution of the diameter of the platinum-loaded single-crystal spherical carbon nanoparticles, as described above. Furthermore, when aromatic compound anions with high reduction power are present in the solvent, low temperature storage is also preferable in terms of the stability of the solvent after the reduction liquid is prepared. This is because when the storage temperature of the reduction liquid is high and a cyclic ether such as THF is used as a solvent, a reductive polymerization reaction of THF, etc. is caused by the aromatic compound anions. When such polymerization product is generated due to the polymerization of the cyclic ether such as THF, the ring-opened compound of THF produced by reduction of carbon halide will be included in the single-crystal spherical carbon nanoparticles. Thus, it is necessary to suppress the polymerization reaction. Examples of a THF polymerization reaction inhibitor include a phenol-based polymerization inhibitor added to suppress production of a peroxide of the cyclic ethers such as THF, preferably BHT (2,6-di-tert-butyl-4-methylphenol). In addition, a solvent can be further stabilized by using a solvent with higher stability than THF, such as 2-methyltetrahydrofuran.

### (Method of Producing Platinum-Loaded Single-Crystal Spherical Carbon Nanoparticles: Apparatus)

The platinum-loaded single-crystal spherical carbon nanoparticles of the present invention can be produced, for example, by mixing a single-crystal spherical carbon nanoparticle raw material liquid (Liquid B) with a platinum-loaded single-crystal spherical carbon nanoparticle reduction liquid (Liquid A), and then continuously mixing the mixture with a liquid containing a platinum raw material (Liquid C), in a thin film fluid formed between two processing surfaces arranged opposite each other, which are capable of approaching and separating, and at least one of which rotates relative to the other.

Examples of the apparatus used in the production method of the present invention include a fluid processing apparatus as proposed by the present applicant and described in JP 2009-112892. The apparatus comprises a stirring tank having an inner peripheral surface which cross-section is circular, and a mixing tool attached to the stirring tank with a slight gap to the inner peripheral surface of the stirring tank, wherein the stirring tank comprises at least two fluid inlets and at least one fluid outlet; from one of the fluid inlets, the first fluid to be processed containing one of the reactants among the fluids to be processed is introduced into the stirring tank; from one fluid inlet other than the above inlet, the second fluid to be processed containing one of reactants different from the above reactant is introduced into the stirring tank through a different flow path. At least one of the stirring tank and the mixing tool rotates at a high speed relative to the other to let the above fluids be in a state of a thin film; and in the above thin film, the reactants contained in the first and second fluids to be processed are reacted. Examples of the apparatus also include an apparatus based on the same principle as the fluid processing apparatus described in Patent Literatures 6 and 7.

Preferably, the single-crystal spherical carbon nanoparticles are produced by mixing a single-crystal spherical carbon nanoparticle raw material liquid (Liquid B) and a platinum-loaded single-crystal spherical carbon nanoparticle reduction liquid (Liquid A) in the thin film fluid. The single-crystal spherical carbon nanoparticles are produced in two steps in which at first, a graphene layer as nuclei of the single-crystal spherical carbon nanoparticle is generated, and then the single-crystal spherical carbon nanoparticles are grown by stacking them on top of each other. Furthermore, platinum-loaded single-crystal spherical carbon nanoparticles can be produced by mixing the mixture with a platinum raw material liquid (Liquid C). When producing platinum-loaded single-crystal spherical carbon nanoparticles, if Liquid A at a temperature of less than 20 °C is used to mix with Liquid B to start the reduction reaction, the frequency of generation of nuclei for the growth of single-crystal spherical carbon nanoparticles is reduced, so that the frequency of contact between the graphene layers, which are the nuclei of the single-crystal spherical carbon nanoparticles, can be suppressed. In this way, by controlling the generation rate of the crystal nuclei of the single-crystal spherical carbon nanoparticles, the platinum-loaded single-crystal spherical carbon nanoparticles can be made fine.

In the production of platinum-loaded single-crystal spherical carbon nanoparticles, when carbon tetrachloride, carbon tetrabromide, or carbon tetraiodide is used as the raw material for single-crystal spherical carbon nanoparticles and is reduced with a platinum-loaded single-crystal spherical carbon nanoparticle reduction liquid to produce single-crystal spherical carbon nanoparticles, lithium chloride, lithium bromide, or lithium iodide is generated as a by-product. These by-products have high solubility in an ether-based solvent, and therefore have the advantage of being easily separated from the platinum-loaded single-crystal spherical carbon nanoparticles by centrifugation.

### 3. Application of Platinum-Loaded Single-Crystal Spherical Carbon Nanoparticles

The platinum-loaded single-crystal spherical carbon nanoparticles produced by the production method of the present invention can be used, for example, in a non-toxic catalyst, a light-emitting element, a luminescent material that produce fluorescence, a negative electrode of a lithium ion battery, an electrode material for a solar cell, a fuel cell catalyst, and a bonding material for a semiconductor device to other substrates, etc.

### EXAMPLE

Hereinafter, the present invention is explained in more detail with reference to Examples, but the present invention is not limited only to these Examples.

### (Preparation of Sample for Transmission Electron Microscope (TEM) Observation)

The platinum-loaded single-crystal spherical carbon nanoparticles obtained in Examples and Comparative Examples were dispersed in THE at a concentration of approximately 0.001% in a vessel. The vessel containing the obtained dispersion was introduced into a glove box under an argon atmosphere, and the dispersion was dropped onto a carbon support membrane and dried to obtain a sample for TEM observation.

### (TEM Observation)

A transmission electron microscope JEM-2100 (JEOL Ltd.) was used for TEM observation of the platinum-loaded single-crystal spherical carbon nanoparticles. The above sample for TEM observation was used as a sample. The observation condition was an accelerating voltage of 200 kV and an observation magnification of 10,000 times or more. The particle diameter was calculated from the distance between the maximum outer circumferences of the platinum-loaded single-crystal spherical carbon nanoparticles observed by TEM, and the average value (average particle diameter) of the results of measuring the diameters of the 50 platinum-loaded single-crystal spherical carbon nanoparticles was calculated.

### (Scanning Transmission Electron Microscope and Energy Dispersive X-Ray Spectrometer: STEM-EDS Analysis)

For the mapping and quantification of elements contained in the platinum-loaded single-crystal spherical carbon nanoparticles by STEM-EDS analysis, the atomic resolution analytical electron microscope JEM-ARM200F (JEOL Ltd.) equipped with the energy dispersive X-ray analyzer Centurio (JEOL Ltd.) was used. The observation condition was the acceleration voltage of 200 kV and the observation magnification of 50,000 times or more, and a beam diameter of 0.2 nm was used for analysis.

### (Infrared (IR) Absorption Spectrum)

The IR absorption spectrum of the platinum-loaded single-crystal spherical carbon nanoparticles was measured using the Fourier transform infrared spectrophotometer FT/IR-6600 (JASCO Corporation) incorporated with ATR PRO 470-H which is an accessory of FT/IR-6600 by Attenuated total reflection (ATR) method. The measurement condition was the resolution of 4.0 cm⁻¹, and accumulated number of 128 times, diamond prism was PKS-D1F wide area (refractive index of 2.4), and the incident angle was 45°. An infrared (IR) absorption spectrum measured for the THF solution of metal lithium which was the reduction liquid, and the platinum-loaded single-crystal spherical carbon nanoparticles produced in Examples and Comparative Examples are referred to as the IR spectrum. The waveform separation was carried out by curve fitting using a spectrum analysis program attached to the control software of the FT/IR-6600 so that the residual sum of squares was 0.05 or less.

### (Confirmation of Generation of Aromatic Compound Anion by IR Spectrum)

The case of naphthalene will be explained as an example of an aromatic compound. Metal lithium was added to a THE solution in which naphthalene was dissolved to generate a naphthalene anion, which are reduction species, and the generation was confirmed by IR absorption spectroscopy. The measurement sample was prepared by dropping the reduction liquid onto a potassium bromide (KBr) plate in a glove box under an argon atmosphere, covering the dropped solution with another KBr plate, and holding it with MagHoldIR (Jusco Engineering, Co., Ltd.). Then, it was taken out of the glove box under an argon atmosphere. This sample was measured by a transmission method using a Fourier transform infrared spectrophotometer FT/IR-6600 (JASCO Corporation). The measurement condition was a resolution of 4.0 cm⁻¹ and an integration count of 8 times.

### (Confirmation of Generation of Aromatic Compound Anion by NMR Spectrum)

Generation of an aromatic compound anion is explained using naphthalene as an example. The generation of a naphthalene anion can be determined from the chemical shift of nuclear magnetic resonance (NMR). In ¹H-NMR which focuses on hydrogen atoms, the hydrogen atoms bonded to the carbon atoms of naphthalene are divided into two Ha and HR, and can be determined from the change in chemical shift shown by these. Since a naphthalene anion accepts an electron generated by dissolution of metal lithium, it is necessary to evaluate the state of bonding with lithium cation. This state can be evaluated by focusing on the lithium cation using ⁷Li-NMR. The measurement sample was filled in a quartz sample tube with the reduction liquid in an argon glove box, sealed, and then taken out. Using a 400 MHz NMR ECS-400 (JEOL Ltd.), ⁷Li-NMR spectrum and ¹H-NMR spectrum were performed respectively for the measurement of the lithium cation and the hydrogen atom in the measurement sample at room temperature with a sample rotation frequency of 15 Hz. In order to measure the state in the reduction reaction solution as it is, the software No-D NMR (Ver. 5) (JEOL Ltd.) was used, which can be performed only with the reduction liquid without using a deuterium solvent. When THF was used as the solvent, the NMR spectrum measurement by this software was performed by automatically extracting the NMR spectrum of THF, and the ¹H-NMR spectrum was measured using this as a reference substance. For ⁷Li-NMR, lithium chloride (LiCl) was mixed into the reduction liquid as a reference substance and the measurement was performed.

### (Fluorescence Spectrum)

The fluorescence spectrum of the platinum-loaded single-crystal spherical carbon nanoparticles was measured using the spectrofluorometer FT-6500 (JASCO Corporation). The above sample liquid dispersed in THF was used as a sample. The sample was placed in a quartz cell (optical path length: 1 cm) in a glove box under an argon atmosphere, the upper part was sealed, and then it was removed from the glove box and measured. The measurement condition was: the excitation bandwidth of 3 nm, fluorescence bandwidth of 3 nm, response of 0.1 seconds, scan rate of 100 nm/min, and data acquisition interval of 0.5 nm.

### (Circularity)

Circularity was calculated as an index for evaluating the sphericity of the platinum-loaded single-crystal spherical carbon nanoparticles as follows. For the circularity of the platinum-loaded single-crystal spherical carbon nanoparticles, the image obtained by TEM observation was approximated to ellipse by using the software iTEM for TEM image (Olympus Soft Imaging Solutions, GmbH). Next, the major axis (D), perimeter (Z) and area (S) of the ellipse obtained from the projected image of the platinum-loaded single-crystal 5 spherical carbon nanoparticles, were determined from the analysis results of the TEM image analysis software. By using the values of the perimeter (Z) and the area (S), 4πS/Z² was calculated to obtain the circularity. As the circularity value is closer to 1, the particle is closer to a spherical shape. When the shape of the particle is truly spherical, the circularity is maximum 1. In addition, an average value of the major axis (D) of the ellipse was determined and defined as the average particle diameter. The measurements were calculated for 50 independent platinum-loaded single-crystal spherical carbon nanoparticles.

### (X-Ray Diffraction: XRD)

For XRD measurement, a powder X-ray diffraction measurement device EMPYREAN (Spectris Corporation, Malvern Panalytical Division) was used. The measurement condition was: measurement range: 10 to 100 [⁰28], Cu anticathode, tube voltage 45 kV, tube current 40 mA, and scanning speed 0.013°/min.

### Example 1

In Example 1, platinum-loaded single-crystal spherical carbon nanoparticles were continuously produced without exposure to the atmosphere by reducing a THE solution in which carbon tetrachloride (CCl₄) being a single-crystal spherical carbon nanoparticle raw material was dissolved (single-crystal spherical carbon nanoparticle raw material liquid (Liquid B)), with a THE solution in which metal lithium was dissolved in a naphthalene-dissolved THE solution (platinum-loaded single-crystal spherical carbon nanoparticle reduction liquid (Liquid A)) to produce single-crystal spherical carbon nanoparticles, and by continuously mixing the obtained mixture with a THE solution of hydrogen hexachloroplatinate (IV) hexahydrate (platinum raw material liquid (Liquid C)). Table 1 shows the formulations of Example 1-1 to Example 1-4.

TABLE 1

| | | | | | Second fluid | | | |
|---|---|---|---|---|---|---|---|---|
| | | | | | (Liquid B) | | | |
| | First fluid (Liquid A) | | | | (Single-crystal | | Third fluid | |
| | (Platinum-loaded single-crystal | | | | spherical carbon | | (Liquid C) | |
| | spherical carbon nanoparticle | | | | nanoparticle raw | | (Platinum raw | |
| | reduction liquid) | | | | material liquid) | | material liquid) | |
| | Raw | | Raw | | Raw | | Raw | |
| | material | [mol/L] | material | [mol/L] | material | [mol/L] | material | [mol/L] |
| Example 1-1 to | Li | 0.0515 | C₁₀H₈ | 0.0515 | CCl₄ | 0.1 | H₂PtCl₆•6H₂O | 0.003 |
| Example 1-4 | | | | | | | | |

The solvent used in Example 1 is super dehydrated tetrahydrofuran with residual water of 10 ppm or less (FUJIFILM Wako Pure Chemical Corporation). The platinum-loaded single-crystal spherical carbon nanoparticle reduction liquid (Liquid A), the single-crystal spherical carbon nanoparticle raw material liquid (Liquid B) and the platinum raw material liquid (Liquid C) were prepared in a glove box under an argon atmosphere. Specifically, the platinum-loaded single-crystal spherical carbon nanoparticle reduction liquid (Liquid A) was prepared at a preparation temperature of 20 °C by dissolving metal lithium in a THE solution in which naphthalene had been dissolved at a concentration of 0.0515 mol/L with a glass-coated magnetic stirrer such that the concentration of metal lithium became 0.0515 mol/L. The single-crystal spherical carbon nanoparticle raw material liquid (Liquid B) was prepared by dissolving carbon tetrachloride which was a single-crystal spherical carbon nanoparticle raw material in THF, and stirring the solution with a glass-coated magnetic stirrer for at least 60 minutes. The platinum raw material liquid (Liquid C) was prepared by dissolving hydrogen hexachloroplatinate (IV) hexahydrate which was a platinum raw material in THE and stirring the solution with a Teflon-coated magnetic stirrer for at least 60 minutes. Regarding the substances indicated by chemical formulas or abbreviations in Table 1, CCl₄ is carbon tetrachloride (Kanto Chemical Co., Ltd.), Li is metal lithium (Kishida Chemical Co., Ltd.), C₁₀H₈ is naphthalene (Kanto Chemical Co., Ltd.), and H₂PtCl₆·6H₂O is hydrogen hexachloroplatinate (IV) hexahydrate (Kishida Chemical Co., Ltd.).

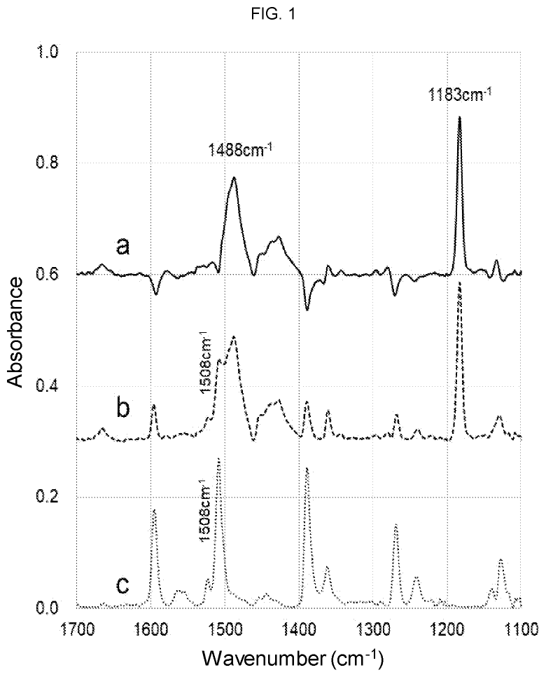

The generation of a naphthalene anion in Liquid A is confirmed by IR absorption spectrum. FIG. 1c shows the result of subtracting the IR absorption spectrum of the solvent THE from the IR absorption spectrum of a THE solution in which only naphthalene was dissolved. FIG. 1b shows the result of subtracting the IR absorption spectrum of the solvent THE from the IR absorption spectrum of the naphthalene THE solution in which metal lithium is dissolved. FIG. 1a is the result of adjusting the intensity of the IR absorption spectrum of FIG. 1c so that the intensity of the IR absorption spectrum of 1508 cm⁻¹ of FIG. 1c matches the absorbance of 1508 cm⁻¹ of FIG. 1b, and subtracting the IR absorption spectrum in FIG. 1c from the IR absorption spectrum in FIG. 1b. The peaks at 1488 cm⁻¹ and 1183 cm⁻¹ observed in FIG. 1a indicate that a naphthalene anion was generated by the transfer of an electron generated by dissolving metal lithium to the LUMO of naphthalene.

The particle diameter of the produced single-crystal spherical carbon nanoparticles is distributed by changing the reduction power of the Liquid A. Therefore, it is preferable to check the reduction power. In particular, the absorption peak of 1183 cm⁻¹ is steep and can be measured as a single peak, so the reduction power can be clearly determined by the decrease in the intensity of this absorption peak. It is confirmed that as the reduction power decreases, the intensity of this absorption peak decreases significantly.

It was confirmed that when biphenyl or anthracene was used as an aromatic compound, the anion of biphenyl or anthracene in Liquid A had 1160 cm⁻¹ or 1175 cm⁻¹ respectively. Decrease of the reduction power of these aromatic compounds is also determined by the intensity of their respective absorption peaks.

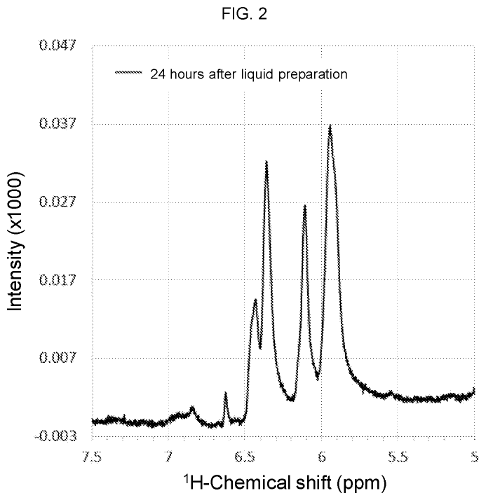

FIG. 2 shows the ¹H-NMR spectrum measured 24 hours after preparing the lithium metal-dissolved naphthalene THE reduction liquid used as Liquid A. When only naphthalene is dissolved in THE solvent, the two hydrogen atoms show the chemical shifts at 7.42 ppm and 7.82 ppm, which are derived from the two hydrogen atoms Hp and Ha of the neutral naphthalene molecule. In contrast, in the case of the naphthalene anion that accepted an electron generated by dissolution of lithium metal into its LUMO, two peaks at 5.9 ppm and 6.1 ppm and two peaks at 6.35 ppm and 6.4 ppm are observed. Naphthalene anion (NPT^{⋅-}) and lithium cation (Li⁺) can exist in a state where they are bound via the solvent THE (NPT^{⋅-}·THF·Li⁺), or in a state where they are directly bound without THE (NPT^{⋅-}·Li⁺). The two peaks at 6.35 ppm and 6.4 ppm, and the two peaks at 5.9 ppm and 6.1 ppm are thought to reflect the state where the naphthalene anion and lithium cation are bound by Coulomb force in the presence of THF.

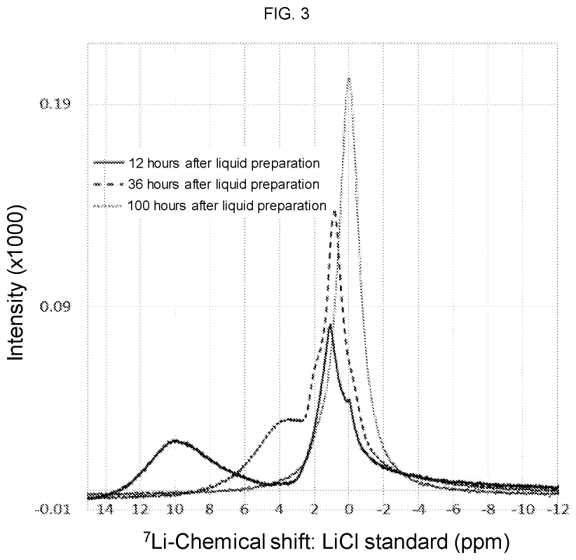

FIG. 3 shows the result of measuring the metal lithium-dissolved naphthalene THE reduction liquid of Liquid A by ⁷Li-NMR. It was found that after 12 hours of preparation, peaks were observed at 1 ppm and 10 ppm, and after 36 hours, the independent peak at 10 ppm shifted to 4 ppm, and after 100 hours, the peak shifted to 0 ppm. Regarding the reduction power of the reduction liquid confirmed at 0 ppm after 100 hours, the reduction liquid was dark green, indicating the presence of the naphthalene anions, but almost no platinum-loaded carbon nanoparticles were obtained. Therefore, it was determined that even in the presence of the naphthalene anion showing the peak at 0 ppm, the naphthalene anion was in a state in which the naphthalene anion solvated with THE and lithium cation solvated with THE were bonded by Coulomb force (THF·NPT^{⋅-}·THF)·(THF·Li⁺·THF). When lithium chloride (LiCl) was dissolved in THE as a reference substance, the peak was narrow and sharp. Therefore, the broadened peak width at a chemical shift of 0 ppm means that the solution structure is one in which the naphthalene anions are present around lithium cations.

Next, the prepared platinum-loaded single-crystal spherical carbon nanoparticle reduction liquid (Liquid A), single-crystal spherical carbon nanoparticle raw material liquid (Liquid B), and platinum raw material liquid (Liquid C) were mixed using a fluid processing apparatus described in Patent Literature 6 by the applicant of the present application. Here, the fluid processing apparatus described in Patent Literature 6 is the apparatus described in FIG. 1 (B) of Patent Literature 6, in which the openings d20 and d30 of the second and third introduction parts are concentric annular shapes surrounding the central opening of the processing surface 2, which is a disk formed in a ring shape. Specifically, the platinum-loaded single-crystal spherical carbon nanoparticle reduction liquid (Liquid A) was introduced between the processing surfaces 1 and 2 from the first introduction part d1, and while the processing part 10 was rotated at a rotation speed of 700 to 5000 rpm, the single-crystal spherical carbon nanoparticle raw material liquid (Liquid B) was introduced between the processing surfaces 1 and 2 from the second introduction part d2, and the platinum-loaded single-crystal spherical carbon nanoparticle reduction liquid and the single-crystal spherical carbon nanoparticle raw material liquid were mixed in the thin film fluid to precipitate the single-crystal spherical carbon nanoparticles between the processing surfaces 1 and 2. Next, the platinum raw material liquid (Liquid C) was introduced between the processing surfaces 1 and 2 from the third introduction part d3, and mixed with the mixed fluid containing the single-crystal spherical carbon nanoparticles in the thin film fluid. Platinum particles were loaded on the surface of the single-crystal spherical carbon nanoparticles, and a discharged liquid containing the platinum-loaded single-crystal spherical carbon nanoparticles (hereinafter, platinum-loaded single-crystal spherical carbon nanoparticle dispersion) was discharged from the space between the processing surfaces 1 and 2 of the fluid processing apparatus. The discharged platinum-supporting single-crystal spherical carbon nanoparticle dispersion was collected in a beaker via a vessel.

Table 2 shows the operation conditions of the fluid processing apparatus. Here, the introduction temperature (liquid sending temperature) and introduction pressure (liquid sending pressure) of Liquid A, Liquid B and Liquid C shown in Table 2 were measured using a thermometer and a pressure gauge provided in the sealed introduction path (first introduction part d1, second introduction part d2, and third introduction part d3) between the processing surfaces 1 and 2. The introduction temperature of Liquid A shown in Table 2 is the actual temperature of Liquid A under the introduction pressure in the first introduction part d1, the introduction temperature of Liquid B is the actual temperature of Liquid B under the introduction pressure in the second introduction part d2, and the introduction temperature of Liquid C is the actual temperature of Liquid C under the introduction pressure in the third introduction part d3. The liquid sending temperature is 20 °C, and the liquid sending pressure is 0.1 MPaG or less.

TABLE 2

| | | | | | Introduction | Introduction |
|---|---|---|---|---|---|---|
| | | | | | temperature | pressure |
| | Disk | Introduction flow rate | | | (liquid sending | (liquid sending |
| | rotation | (liquid sending flow rate) | | | temperature) | pressure) |
| | speed | [mL/min] | | | [°C] | [MPaG] |
| | [rpm] | Liquid A | Liquid B | Liquid C | Liquids A to C | Liquids A to C |
| Example 1-1 | 5000 | 40 | 5 | 5 | 20 | <0.1 |
| Example 1-2 | 3500 | | | | | |
| Example 1-3 | 2100 | | | | | |
| Example 1-4 | 700 | | | | | |

A wet cake sample was prepared from the platinum-loaded single-crystal spherical carbon nanoparticle dispersion discharged from the fluid processing apparatus and recovered in a beaker. The preparation method was performed according to a conventional method. The discharged platinum-loaded single-crystal spherical carbon nanoparticle dispersion was recovered, the platinum-loaded single-crystal spherical carbon nanoparticles were sedimented from the recovered liquid by centrifugation (30190 G, 2 hours), and the supernatant was removed. After the removal, ultrasonic washing with THE and sedimentation were repeated, and the finally obtained platinum-loaded single-crystal spherical carbon nanoparticles were dried at −0.10 MPaG at 25 °C for 20 hours to obtain a dry powder sample.

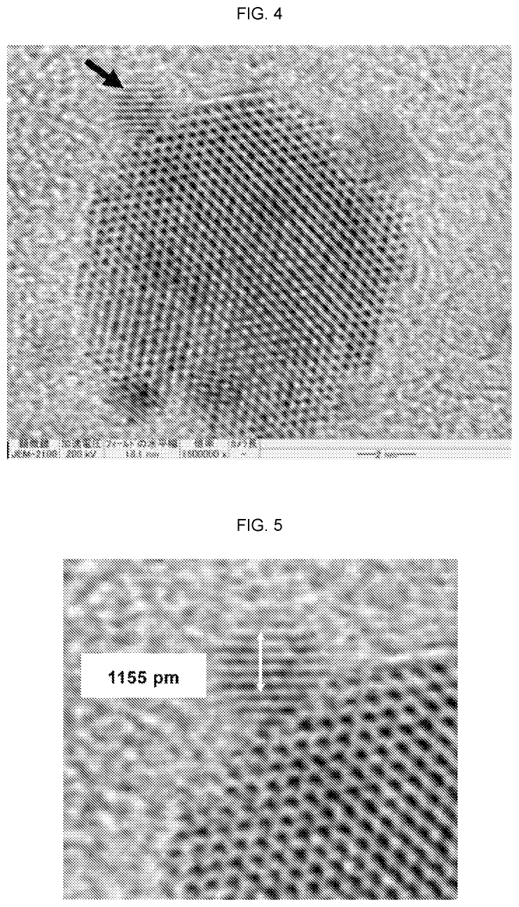

FIG. 4 shows a TEM image of the platinum-loaded single-crystal spherical carbon nanoparticles produced in Example 1-1. Similar results were confirmed for the platinum-loaded single-crystal spherical carbon nanoparticles of Examples 1-2 to 1-4. Since lattice fringes were observed in one direction, it was confirmed that the platinum-loaded single-crystal spherical carbon nanoparticles were single-crystals. As an example of the lattice spacing of the single-crystal spherical carbon nanoparticles, the measured length of 5 lattice spacings of 1580 pm was divided by 5 to obtain 316 pm. As an example of the lattice spacing of the loaded platinum particles, as shown in FIG. 5, the measured length of 5 lattice spacings of 1155 pm was divided by 5 to obtain 231 pm. These were assigned to the carbon (003) plane and the platinum (111) plane, respectively.

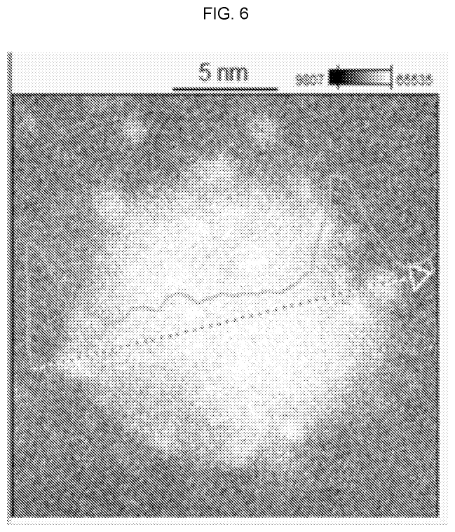

FIG. 6 shows the result of superimposing the STEM observation image of the platinum-loaded single-crystal spherical carbon nanoparticles produced in Example 1-2 and the detection intensity obtained by linear analysis of the platinum particles by STEM-EDS. It was confirmed that high intensity of platinum was detected on the surface side of the platinum-loaded spherical carbon nanoparticles, and the platinum particles were loaded on the surface of the single-crystal spherical carbon nanoparticles. In addition, platinum was also detected inside the platinum-loaded single-crystal spherical carbon nanoparticles. This indicates that the platinum particles are in a state where the platinum particles are adsorbed and coated on the surface of the single-crystal spherical carbon particles, while the particle diameter of the platinum particles is about 1 nm and smaller than about 3 nm of the particle diameter of the platinum particles in the commonly known platinum-loaded carbon powders. This result indicates that the platinum particles are more uniformly loaded on the single-crystal spherical carbon nanoparticles, which state is different from the state observed for the conventional platinum-loaded carbon powders wherein the region on which the platinum particles are covered and the uncovered region can be distinguished. The fact that platinum particles are uniformly loaded on the surface of the single-crystal spherical carbon nanoparticles in this manner indicates that the single-crystal carbon nanoparticles produced by the present invention are spherical, and that the platinum particles are not loaded on the single-crystal carbon nanoparticles in an aggregated state.

### (C—H Bond)

FIG. 7 shows the result of waveform separation of the wavenumber range of 2800 cm⁻¹ to 3000 cm⁻¹ in the IR spectrum of the platinum-loaded single-crystal spherical carbon nanoparticles of Example 1-1. Since the absorption peaks at 2856 cm⁻¹ and 2871 cm⁻¹ and the absorption peaks at 2932 cm⁻¹ and 2957 cm⁻¹ are respectively attributed to the CH₃ bond and the CH₂ bond of CH-bond, it was confirmed that the platinum-loaded single-crystal spherical carbon nanoparticles are hydrogenated. The same was confirmed for Examples 1-2, 1-3, and 1-4. The numbers in parentheses indicate the relative area ratio.

FIG. 8 shows the result of waveform separation of the wavenumber range of 900 cm⁻¹ to 1900 cm⁻¹ in the IR spectrum of the platinum-loaded single-crystal spherical carbon nanoparticles of Example 1-1. The peak wavenumber of each band after waveform separation and the relative area ratio in parentheses are shown.

### (C—O Bond)

The IR spectrum of FIG. 8 was divided into eight parts by waveform separation, and the absorption in the wavenumber range of 1000 cm⁻¹ to 1100 cm⁻¹ is attributed to the C—O bond. The ratio of 1056 cm⁻¹ (Band 8) waveform separated in this wavenumber range in the total area (ratio of C—O bond) was 12.2%. The ratio of C—O bond is preferably 2% or more and 15% or less. When the ratio is less than 2%, it will be difficult to disperse the platinum-loaded single-crystal spherical carbon nanoparticles in an aqueous solution. When the ratio exceeds 15%, there is an inconvenience that the circularity of the platinum-loaded single-crystal spheric carbon nanoparticles becomes 0.80 or less, and the deviation from sphericity will increase, which in turn will disadvantageously lead to a decrease in sphericity.

The C—O bonds of the platinum-loaded single-crystal spherical carbon nanoparticles are formed by controlling the water content to always be 10 ppm or less, when the platinum-loaded single-crystal spherical carbon nanoparticles are produced by the reduction reaction in ultra-dehydrated THE which is a grade specified with residual water of 10 ppm or less in THF. The surface of the platinum-loaded single-crystal spherical carbon nanoparticles is formed from the loaded platinum particles, C—O bonds, and C—H bonds, and has the characteristic of being easily dispersible in an organic solvent.

### (C—N Bond)

The C—N bond is generated by exposure of the top surface of the graphene layer not protected by oxygen to the air atmosphere during the cleaning and recovery process of the platinum-loaded single-crystal spherical carbon nanoparticles. The presence of the C—N bond also indicates the termination of bond defects in the single-crystal spherical carbon particles by nitrogen. The C—N bond has absorption in the wavenumber range of 1300 cm-1 to 1400 cm⁻¹, so In the IR spectrum of FIG. 8, the C—N bond corresponds to Band 5 with a peak wavenumber of 1371 cm⁻¹, and the relative area ratio (ratio of C—N bonds) is 6.0%. Since the C—N bond together with the C—O bond, has the effect of terminating the defect where the bond of carbon atoms in the graphene layer is broken, the ratio of C—N bond is preferably 10% or less. This C—N bond may not be detectable in case where the C—O bond terminates the carbon atom bond defect.

Since the C—H bond in the platinum-loaded single-crystal spherical carbon nanoparticles confirmed by the IR spectrum in FIG. 7 can make the surface of the single-crystal spherical carbon nanoparticles hydrophobic, the platinum-loaded single-crystal spherical carbon nanoparticles can be well dispersed in an organic solvent. Furthermore, the result shown in FIG. 8 confirmed that dispersibility in an aqueous solvent is also possible due to coexistence of the C—O bond.

Since it is known that absorption at 1600 cm⁻¹ to 1690 cm⁻¹ is observed when there is a C═C bond, Band 2 at 1638 cm⁻¹ showing the maximum intensity confirmed by waveform separation of the IR spectrum in FIG. 8, is thought to indicate a bonding state reflecting the graphite structure of the carbon in the platinum-loaded single-crystal spherical carbon nanoparticles.

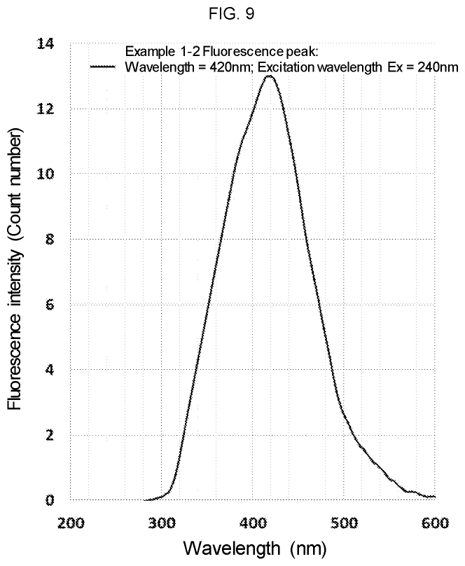

FIG. 9 shows the fluorescence spectrum observed at an excitation wavelength of 240 nm for the platinum-loaded single-crystal spherical carbon nanoparticles of Example 1-2. It was confirmed that the fluorescence peak wavelength was 420 nm, and visible fluorescence was obtained by ultraviolet light of less than 300 nm.

This change in the fluorescence peak wavelength of the platinum-loaded single-crystal spherical carbon nanoparticles is explained by (A) quantum effect mechanism among the above-mentioned three mechanisms (A) to (C). That is, the fluorescence peak wavelength of the platinum-loaded single-crystal spherical carbon nanoparticles is thought to be shifted to the shorter wavelength side because the band gap increases as the particle diameter of the single-crystal spherical carbon nanoparticles decreases. This is a result due to (A) the quantum effect mechanism. Furthermore, the platinum-loaded single-crystal spherical carbon nanoparticles of the present invention are not surface-modified with alkyl groups, amino groups, etc., and do not have (B) the surface modification mechanism among the above-mentioned three mechanisms. It is thought that the fluorescence is produced by a synergistic effect of (C) an oxygen-mediated mechanism due to the bonding of oxygen to the particles and (A) a quantum effect mechanism.

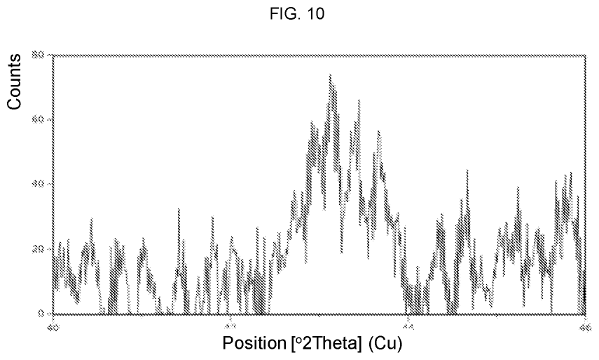

FIG. 10 shows X-ray diffraction patterns of the platinum-loaded single-crystal spherical carbon nanoparticles of Example 1-4. Graphite crystal has a structure in which graphene layers in which C═C bonds formed by carbon atoms with sp2 hybrid orbital form a planar layer are stacked in the c-axis direction. Graphite with hexagonal crystals as a crystal form can form a simple lattice and a rhombohedral lattice as a space lattice. The peaks at diffraction angles 26 of 42.2° and 44.6° appear due to a simple lattice of hexagonal structure, whereas the peak at diffraction angle 26 of 43.3° appear due to a rhombohedral lattice. It is meant that when the single-crystal spherical carbon nanoparticles with a hexagonal crystal structure have a simple lattice as a space lattice, if the two graphene layers are A layer and B layer, they have a stacked structure like ABABAB . . . , and when the single-crystal spherical carbon nanoparticles with a hexagonal crystal structure have a rhombohedral lattice, if the three graphene layers are layer A, layer B, and layer C, they have a stacked structure like ABCABCABC . . . . Therefore, the presence of a diffraction peak at 2θ of about 43° obtained in FIG. 10 indicates that the spatial lattice of the single-crystal spherical carbon nanoparticles is a rhombohedral lattice.

Table 3 shows the average particle diameter, average circularity, average lattice spacing of the graphene layers of the carbon particles, average lattice spacing of the platinum particles, the ratio of the C—O bond obtained by the IR spectrum, and the fluorescence peak wavelength measured at an excitation wavelength of 240 nm of the platinum-loaded single-crystal spherical carbon nanoparticles of Examples 1-1 to 1-4.

TABLE 3

| | | | Average | Average | | Fluoresence |
|---|---|---|---|---|---|---|
| | | | lattice | lattice | | peak wavelength |
| | Average | | spacing of | spacing of | IR ratio | [nm] at |
| | particle | | carbon | platinum | of C—O | excitation |
| | diameter | Average | particles | particles | bond | wavelength |
| | [nm] | circularity | [pm] | [pm] | [%] | 240 nm |
| Example 1-1 | 12.0 | 0.88 | 316 | 227 | 7.5 | 420 |
| Example 1-2 | 14.5 | 0.88 | 320 | 228 | 7.5 | 420 |
| Example 1-3 | 15.6 | 0.87 | 322 | 227 | 7.7 | 422 |
| Example 1-4 | 19.6 | 0.85 | 320 | 228 | 8.0 | 421 |

### Comparative Example 1

The formulation of Comparative Example 1 was the same as that of Example 1 shown in Table 1, but as shown in Table 4, the disk rotation speed was lowered to 600 rpm or 500 rpm to produce platinum-loaded single-crystal spherical carbon nanoparticles. Table 5 shows the results of the platinum-loaded single-crystal spherical carbon nanoparticles obtained. By reducing the disk rotation speed to less than 700 rpm, no change was observed in the crystal structure.

TABLE 4

| | | | | | Introduction | Introduction |
|---|---|---|---|---|---|---|
| | | | | | temperature | pressure |
| | Disk | Introduction flow rate | | | (liquid sending | (liquid sending |
| | rotation | (liquid sending flow rate) | | | temperature) | pressure) |
| | speed | [mL/min] | | | [°C] | [MPaG] |
| | [rpm] | Liquid A | Liquid B | Liquid C | Liquids A to C | Liquids A to C |
| Comparative | 600 | 40 | 5 | 5 | 20 | <0.1 |
| Example 1-1 | | | | | | |
| Comparative | 500 | | | | | |
| Example 1-2 | | | | | | |

TABLE 5

| | | | Average | Average | | Fluoresence |
|---|---|---|---|---|---|---|
| | | | lattice | lattice | | peak wavelength |
| | Average | | spacing of | spacing of | IR ratio | [nm] at |
| | particle | | carbon | platinum | of C—O | excitation |
| | diameter | Average | particles | particles | bond | wavelength |
| | [nm] | circularity | [pm] | [pm] | [%] | 240 nm |
| Comparative | 20.5 | 0.78 | 318 | 227 | 11.0 | 422 |
| Example 1-1 | | | | | | |
| Comparative | 22.8 | 0.77 | 320 | 227 | 11.2 | 422 |
| Example 1-2 | | | | | | |

### Example 2

Example 2 shows the results of the production of the platinum-loaded single-crystal spherical carbon nanoparticles wherein the temperature of the platinum-loaded single-crystal spherical carbon particle reduction liquid (Liquid A) was 5 °C, and the disk rotation speed was 5000 rpm to 2100 rpm. The formulations of the platinum-loaded single-crystal spherical carbon nanoparticle reduction liquid (Liquid A) and the single-crystal spherical carbon nanoparticle raw material liquid (Liquid B) were the same as in Example 1, and were prepared under the conditions shown in Table 1. Table 6 shows the production conditions of Example 2, and the results of the obtained platinum-loaded single-crystal spherical carbon nanoparticles are as shown in Table 7. In the platinum-loaded single-crystal spherical carbon nanoparticles produced in Example 2, the average particle diameter became smaller as the disk rotation speed increased.

TABLE 6

| | | | | | | | | Introduction |
|---|---|---|---|---|---|---|---|---|
| | | | | | | | | pressure |
| | Disk | Introduction flow rate | | | Introduction temperature | | | (liquid sending |
| | rotation | (liquid sending flow rate) | | | (liquid sending temperature) | | | pressure) |
| | speed | [mL/min] | | | [°C] | | | [MPaG] |
| | [rpm] | Liquid A | Liquid B | Liquid C | Liquid A | Liquid B | Liquid C | Liquids A to C |
| Example 2-1 | 5000 | 40 | 5 | 5 | 5 | 20 | 20 | <0.1 |
| Example 2-2 | 3500 | | | | | | | |
| Example 2-3 | 2100 | | | | | | | |

TABLE 7

| | | | Average | Average | | Fluoresence |
|---|---|---|---|---|---|---|
| | | | lattice | lattice | | peak wavelength |
| | Average | | spacing of | spacing of | IR ratio | [nm] at |
| | particle | | carbon | platinum | of C—O | excitation |
| | diameter | Average | particles | particles | bond | wavelength |
| | [nm] | circularity | [pm] | [pm] | [%] | 240 nm |
| Example 2-1 | 10.5 | 0.86 | 319 | 228 | 7.8 | 421 |
| Example 2-2 | 13.3 | 0.83 | 320 | 228 | 7.5 | 423 |
| Example 2-3 | 14.6 | 0.84 | 321 | 228 | 7.6 | 422 |

### Comparative Example 2

The formulation of Comparative Example 2 was the same as that of Example 1 shown in Table 1, but as shown in Table 8, the disk rotation speed was lowered to 700 rpm or 500 rpm, and the temperatures of the platinum-loaded single-crystal spherical carbon nanoparticle reduction liquid (Liquid A) was 0 °C, to produce platinum-loaded single-crystal spherical carbon nanoparticles. Table 9 shows the results of the platinum-loaded single-crystal spherical carbon nanoparticles obtained. By reducing the disk rotation speed to 700 rpm or 500 rpm, and setting the temperature of Liquid A to be 5 °C, the average circularity the single-crystal spherical carbon nanoparticles became less than 0.9.

TABLE 8

| | | | | | | | | Introduction |
|---|---|---|---|---|---|---|---|---|
| | | | | | | | | pressure |
| | Disk | Introduction flow rate | | | Introduction temperature | | | (liquid sending |
| | rotation | (liquid sending flow rate) | | | (liquid sending temperature) | | | pressure) |
| | speed | [mL/min] | | | [°C] | | | [MPaG] |
| | [rpm] | Liquid A | Liquid B | Liquid C | Liquid A | Liquid B | Liquid C | Liquids A to C |
| Comparative | 700 | 40 | 5 | 5 | 5 | 20 | 20 | <0.1 |
| Example 2-1 | | | | | | | | |
| Comparative | 500 | | | | | | | |
| Example 2-2 | | | | | | | | |

TABLE 9

| | | | Average | Average | | Fluoresence |
|---|---|---|---|---|---|---|
| | | | lattice | lattice | | peak wavelength |
| | Average | | spacing of | spacing of | IR ratio | [nm] at |
| | particle | | carbon | platinum | of C—O | excitation |
| | diameter | Average | particles | particles | bond | wavelength |
| | [nm] | circularity | [pm] | [pm] | [%] | 240 nm |
| Comparative | 15.6 | 0.78 | 320 | 228 | 12.3 | 423 |
| Example 2-1 | | | | | | |
| Comparative | 16.4 | 0.77 | 320 | 227 | 12.4 | 423 |
| Example 2-2 | | | | | | |

### Example 3

The formulations of Liquids A, B and C in Example 3 are shown in Table 10. Carbon tetrachloride has four chlorine atoms bonded to a carbon atom, so in order to eliminate all four chlorine atoms and reduce carbon tetrachloride to carbon particles, four times the molar amount of metal lithium and naphthalene in the platinum-loaded single-crystal spherical carbon nanoparticle reduction liquid (Liquid A) is required per mole of carbon tetrachloride. In the formulations of Examples 1 and 2, the molar ratio of the metal lithium and naphthalene in the reduction liquid was set to ⅛ times the molar amount of 1 mole of carbon tetrachloride, and the flow rate of the reduction liquid (Liquid A) during production was set to 8 times the flow rate, in order to relatively lower the naphthalene concentration in the reaction solution during the production of platinum-loaded single-crystal spherical carbon nanoparticles. On the other hand, in Example 3, the metal lithium and naphthalene in the reduction liquid were set to 4 times the molar amount of 1 mole of carbon tetrachloride as in the chemical reaction, and the flow rate ratio of the platinum-loaded single-crystal spherical carbon nanoparticle reduction liquid (Liquid A) to the single-crystal spherical carbon nanoparticle raw material liquid (Liquid B) was set to 1:1, and the platinum-loaded single-crystal spherical carbon nanoparticles were produced by changing the flow rates of Liquids A and B. Table 10 shows the formulations of production of the platinum-loaded single-crystal spherical carbon nanoparticles, and Table 11 shows the production conditions.

TABLE 10

| | | | | | Second fluid | | | |
|---|---|---|---|---|---|---|---|---|
| | | | | | (Liquid B) | | | |
| | First fluid (Liquid A) | | | | (Single-crystal | | Third fluid | |
| | (Platinum-loaded single-crystal | | | | spherical carbon | | (Liquid C) | |
| | spherical carbon nanoparticle | | | | nanoparticle raw | | (Platinum raw | |
| | reduction liquid) | | | | material liquid) | | material liquid) | |
| | Raw | | Raw | | Raw | | Raw | |
| | material | [mol/L] | material | [mol/L] | material | [mol/L] | material | [mol/L] |
| Example 3-1 to | Li | 0.4 | C₁₀H₈ | 0.4 | CCl₄ | 0.1 | H₂PtCl₆•6H₂O | 0.02 |
| Example 3-3 | | | | | | | | |

TABLE 11

| | | | | | Introduction | Introduction |
|---|---|---|---|---|---|---|
| | | | | | temperature | pressure |
| | Disk | Introduction flow rate | | | (liquid sending | (liquid sending |
| | rotation | (liquid sending flow rate) | | | temperature) | pressure) |
| | speed | [mL/min] | | | [°C] | [MPaG] |
| | [rpm] | Liquid A | Liquid B | Liquid C | Liquids A to C | Liquids A to C |
| Example 3-1 | 5000 | 10 | 10 | 10 | 20 | <0.1 |
| Example 3-2 | | 20 | 20 | 10 | | |
| Example 3-3 | | 30 | 30 | 10 | | |

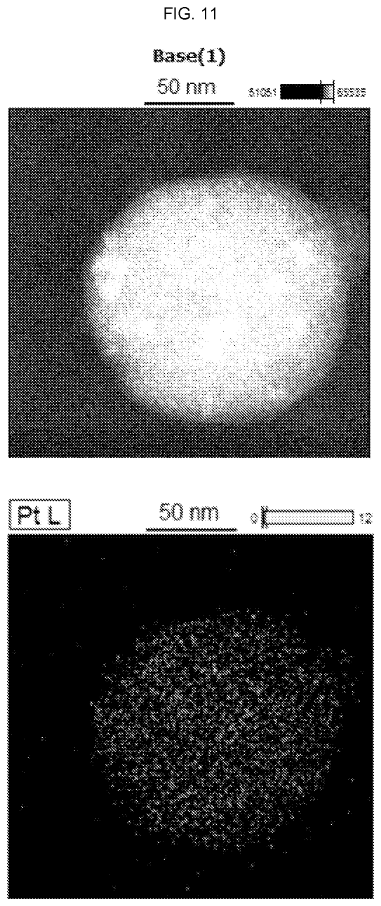

FIG. 11 shows an STEM observation image of the platinum-loaded single-crystal spherical carbon nanoparticles produced in Example 3-1, and the element distribution obtained by STEM-EDS. From these results, it was confirmed that platinum particles were uniformly loaded on the platinum-loaded single-crystal spherical carbon nanoparticles, which was different from the case where platinum particles were randomly loaded on the single-crystal spherical carbon nanoparticles as confirmed in Example 1-1 when the single-crystal spherical carbon particle diameter was about 15 nm. In Examples 3-2 and 3-3, it was confirmed that platinum particles are uniformly loaded on the single-crystal spherical carbon nanoparticles in the same manner.

By producing single-crystal spherical carbon nanoparticles in solution and continuously producing platinum particles according to the present invention, platinum particles as nanoparticles of around 1 nm can be loaded on the single-crystal spherical carbon nanoparticles, and the surface of the single-crystal spherical carbon nanoparticles can be coated with platinum particles using less platinum raw material, which is thought to be useful in terms of protecting precious metal resources.

Table 12 shows the results of the obtained platinum-loaded single-crystal spherical carbon nanoparticles.

TABLE 12

| | | | Average | Average | | Fluoresence |
|---|---|---|---|---|---|---|
| | | | lattice | lattice | | peak wavelength |
| | Average | | spacing of | spacing of | IR ratio | [nm] at |
| | particle | | carbon | platinum | of C—O | excitation |
| | diameter | Average | particles | particles | bond | wavelength |
| | [nm] | circularity | [pm] | [pm] | [%] | 240 nm |
| Example 3-1 | 36 | 0.87 | 317 | 228 | 7.7 | 421 |
| Example 3-2 | 62 | 0.87 | 319 | 228 | 7.7 | 421 |
| Example 3-3 | 86 | 0.89 | 319 | 227 | 8.0 | 422 |

### INDUSTRIAL APPLICABILITY

The production method of the present invention can produce the platinum-loaded single-crystal spherical carbon nanoparticles. The produced platinum-loaded single-crystal spherical carbon nanoparticles have the advantage that they do not have the toxicities to living organisms that compound semiconductors made of cadmium, selenium, tellurium, etc. have, and therefore there is no need to recover the compound semiconductors after use as catalysts or battery materials. Furthermore, because the platinum-loaded single-crystal spherical carbon nanoparticles are spherical, the platinum-loaded single-crystal spherical carbon nanoparticles can be densely packed as electrode materials for solar cells and secondary ion batteries. The platinum-loaded single-crystal spherical carbon nanoparticles can be used for a negative electrode for lithium batteries or an electrode material for solar cells where the electrical conductivity at the contact between carbon nanoparticles is improved by the platinum particles being loaded thereon.

1. A method of producing platinum-loaded single-crystal spherical carbon nanoparticles in which platinum particles are loaded on a surface of single-crystal spherical carbon nanoparticles, the method comprising:
a step of mixing a single-crystal spherical carbon nanoparticle raw material liquid containing a carbon halide and a platinum-loaded single-crystal spherical carbon nanoparticle reduction liquid containing an anion of an aromatic compound generated from lithium, sodium or potassium and the aromatic compound to produce single-crystal spherical carbon nanoparticles; and
a step of continuously adding a platinum raw material liquid containing a platinum halide to the obtained mixture to produce platinum-loaded single-crystal spherical carbon nanoparticles.

2. The method according to claim 1, wherein an average value of a circularity calculated by the formula: 4πS/Z² is 0.8 or more, when using the perimeter (Z) and the area (S) of the projected image of the single-crystal spherical carbon nanoparticle observed by a transmission electron microscope.

3. The method according to claim 1, wherein the average particle diameter of the single-crystal spherical carbon nanoparticles is 1 nm to 200 nm.

4. The method according to claim 1, wherein the single-crystal spherical carbon nanoparticle raw material liquid and the platinum-loaded single-crystal spherical carbon nanoparticle reduction liquid are mixed using an apparatus to produce single-crystal spherical carbon nanoparticles; and continuously the platinum raw material liquid containing a platinum halide is added to the obtained mixture to produce platinum-loaded single-crystal spherical carbon nanoparticles,
wherein the apparatus comprises a fluid pressure imparting mechanism for imparting a predetermined pressure to fluids to be processed; at least two processing members of a first processing member and a second processing member, the second processing member being capable of approaching to and separating from the first processing member; and a rotation drive mechanism for rotating the first processing member and the second processing member relative to each other; and
wherein the at least two processing members provide at least two processing surfaces of a first processing surface and a second processing surface disposed in a position facing with each other,
each of the processing surfaces constitute part of a sealed flow path through which the fluid to be processed under the predetermined pressure is passed,
the processing surfaces are for mixing and reacting two or more fluids to be processed, at least one of which contains a reactant, with each other,
of the first and second processing members, at least the second processing member is provided with a pressure-receiving surface, and at least part of the pressure-receiving surface is comprised of the second processing surface,
the pressure-receiving surface receives pressure applied to the fluids to be processed by the fluid pressure imparting mechanism and thereby generates a force to move in the direction of separating the second processing surface from the first processing surface,
the fluids to be processed under the predetermined pressure are passed between the first and second processing surfaces being capable of approaching to and separating from each other, at least one of which rotates relative to the other, whereby the fluids to be processed form a thin film fluid while passing between the first and second processing surfaces,
the apparatus further comprises an introduction path independent of the flow paths through which the fluids to be processed under the predetermined pressure are passed; and at least one opening leading to the introduction path and being arranged in at least either the first processing surface or the second processing surface, and
at least one of the fluids to be processed is sent from the introduction path and introduced into between the first and second processing surfaces, and a reactant contained at least in any one of the aforementioned fluids to be processed is mixed with the fluids to be processed other than the fluid containing the reactant in the thin film fluid.

5. The method according to claim 4, wherein the opening is located downstream of a point at which the flow of the fluids to be processed that is passed between the two processing surfaces becomes a laminar flow.

6. The method according to claim 1, wherein the molar ratio of the lithium, sodium or potassium and the halogenated carbon is 7:1 to 4:1.

7. The method according to claim 1, wherein the aromatic compound is at least one selected from the group consisting of biphenyl, naphthalene, 1,2-dihydronaphthalene, anthracene, phenanthrene and pyrene.

8. The method according to claim 7, wherein when the aromatic compound is biphenyl, naphthalene or anthracene, an IR absorption spectrum of the platinum-loaded single-crystal spherical carbon nanoparticle reduction liquid shows an absorption peak in the wavenumber range of 1200 cm⁻¹ to 1100 cm⁻¹.

9. The method according to claim 1, wherein when the aromatic compound is biphenyl, naphthalene or anthracene, an ¹H-NMR spectrum of the platinum-loaded single-crystal spherical carbon nanoparticle reduction liquid shows at least four peaks of chemical shifts between 5.5 ppm and 6.5 ppm.

10. The method according to claim 1, wherein when the aromatic compound is biphenyl, naphthalene or anthracene, an ⁷Li-NMR spectrum of the platinum-loaded single-crystal spherical carbon nanoparticle reduction liquid shows a peak of chemical shifts at 2 ppm or more.

11. The method according to claim 1, wherein the solvent contained in the platinum-loaded single-crystal spherical carbon nanoparticle reduction liquid is tetrahydrofuran, 2-methyltetrahydrofuran or dimethoxyethane with residual water of 10 ppm or less.

12. The method according to claim 1, wherein the solvent contained in the platinum-loaded single-crystal spherical carbon nanoparticle reduction liquid is tetrahydrofuran which contains a phenolic polymerization inhibitor, and has residual water of 10 ppm or less and residual oxygen concentration of less than 0.1 ppm.

13. The method according to claim 1, wherein the solvent contained in the single-crystal spherical carbon nanoparticle raw material liquid is tetrahydrofuran, 2-methyltetrahydrofuran, or dimethoxyethane having residual water of 10 ppm or less and residual oxygen concentration of less than 0.1 ppm.

14. The method according to claim 1, wherein the halogenated carbon is carbon tetrachloride, carbon tetrabromide, or carbon tetraiodide.

15. The method according to claim 1, wherein the platinum halide is hydrogen hexachloroplatinate (IV) hexahydrate or platinum chloride (IV).

16. The method according to claim 1, wherein the single-crystal spherical carbon nanoparticles are hexagonal.

17. The method according to claim 1, wherein in an IR absorption spectrum, the platinum-loaded single-crystal spherical carbon nanoparticles have an absorption peak in the wavenumber range of 2800 cm⁻¹ to 3000 cm⁻¹, and the area of the absorption peak of 1000 cm⁻¹ to 1100 cm⁻¹ obtained by waveform separation of the wavenumber range of 900 cm⁻¹ to 1900 cm⁻¹ is 15% or less of the total area of absorption peaks in the wavenumber range of 900 cm⁻¹ to 1900 cm⁻¹.

18. The method according to claim 1, wherein in an IR absorption spectrum of the platinum-loaded single-crystal spherical carbon nanoparticles, the area of the absorption peak of 1300 cm⁻¹ to 1400 cm⁻¹ obtained by waveform separation of the wavenumber range of 900 cm⁻¹ to 1900 cm⁻¹ is 10% or less of the total area of absorption peaks in the wavenumber range of 900 cm⁻¹ to 1900 cm⁻¹.

19. The method according to claim 1, wherein in a fluorescence spectrum, the platinum-loaded single-crystal spherical carbon nanoparticles have a fluorescence maximum in a wavelength range of 400 nm to 500 nm when excited by a light with a wavelength of 240 nm.

20. Platinum-loaded single-crystal spherical carbon nanoparticles in which platinum is loaded on a surface of single-crystal spherical carbon nanoparticles having an average particle diameter of 1 nm to 30 nm.
